(19) United States
(12) Patent Application Publication
(10) Pub. No.: US 2024/0023416 A1
(43) Pub. Date: Jan. 18, 2024

(54) ORGANIC LIGHT EMITTING DIODE DISPLAY PANEL AND DISPLAY DEVICE

(71) Applicant: Hefei Visionox Technology Co., Ltd., Hefei (CN)

(72) Inventors: Chuanzhi XU, Hefei (CN); Zhengfang XIE, Hefei (CN); Junhui LOU, Hefei (CN)

(73) Assignee: Hefei Visionox Technology Co., Ltd., Hefei (CN)

(21) Appl. No.: 18/363,147

(22) Filed: Aug. 1, 2023

Related U.S. Application Data
(63) Continuation of application No. PCT/CN2022/115389, filed on Aug. 29, 2022.

(30) Foreign Application Priority Data
Dec. 21, 2021 (CN) 202111569163.8

(51) Int. Cl. H10K 59/80

(52) U.S. Cl. CPC H10K 59/879; H10K 59/873

(57) ABSTRACT

An organic light emitting diode (OLED) display panel and a display device, which relates to the field of display. The light-transmitting display zone of the OLED display panel includes: a substrate; a plurality of second light-emitting sub-pixels disposed on the substrate and configured to emit a specific color of light during display; a light-transmitting film layer disposed on the exit side of the second light-emitting sub-pixels and configured to scatter or diffuse the colored light of the second light-emitting sub-pixels. The light-transmitting film layer at least includes a low-refractive-index film layer and an adjacent high-refractive-index film layer. The light-transmitting film layer is configured to scatter or diffuse the colored light of the second light-emitting sub-pixels, so that more of light emitted from the second light-emitting sub-pixels is emitted from the region between the second light-emitting sub-pixels.

### CROSS-REFERENCE TO RELATED APPLICATIONS

This application is a continuation of International Application No. PCT/CN2022/115389, filed on Aug. 29, 2022, which claims priority to Chinese Patent Application No. 202111569163.8, entitled with “OLED DISPLAY PANEL AND DISPLAY DEVICE”, and filed with the China National Intellectual Property Administration on Dec. 21, 2021. The disclosures of the aforementioned applications are hereby incorporated by reference in their entireties.

### TECHNICAL FIELD

The present application embodiments relate to the technical field of display technology, and in particular, to an organic light emitting diode display panel and display device.

### BACKGROUND

Organic Light Emitting Diode (OLED for short), as a current-driven-type light-emitting device, is widely used in mobile phones, tablet computers and other display devices due to its various characteristics such as its self-illumination, fast response, wide viewing angle, the ability to be fabricated on flexible substrates.

In order to meet different requirements, the OLED display panel of some display devices is wholly or partially set as a light-transmitting display zone, which can normally display images. However, in order to ensure the light transmittance of OLED display panel in the light-transmitting display zone, the size of light-emitting sub-pixels located in the light-transmitting display zone is relatively small, and the spacing between light-emitting sub-pixels is relatively large, which affects the display effect of the light-transmitting display zone.

### SUMMARY

In view of the above problems, embodiments of the present application provide an OLED display panel and a display device, which can effectively improve the display effect of the light-transmitting display zone.

In order to achieve the above objectives, the present application embodiments provide the following technical solutions.

A first aspect of the present application embodiments provides an OLED display panel, the OLED display panel has a light-transmitting display zone, and the light-transmitting display zone includes: a substrate; a plurality of second light-emitting sub-pixels arranged on the substrate and configured to emit a specific color of light when displayed; a light-transmitting film layer arranged on the exit side of the second light-emitting sub-pixels and configured to scatter or diffuse colored light of the second light-emitting sub-pixels, and the light-transmitting film layer at least includes a low-refractive-index film layer and a high-refractive-index film layer adjacent to the low-refractive-index film layer; and a refractive index of the low-refractive-index film layer is lower than that of the high-refractive-index film layer.

In the OLED display panels provided by the embodiments of the present application, a light-transmitting film layer is provided on the exit side of each second light-emitting sub-pixel in the light-transmitting display zone, and the colored light of the second light-emitting sub-pixel is scattered or diffused by the light-transmitting film layer, which increases the light exit angle of the second light-emitting sub-pixels, in this way, in the light-transmitting display zone, more of the light emitted by the second light-emitting sub-pixels is emitted from a region between the second light-emitting sub-pixels, improving the light exit uniformity in the light-transmitting display zone, thereby improving the display effect of the OLED display panel in the light-transmitting display zone.

A second aspect of the present application embodiments provides a display device, including the OLED display panel as described above;
a photosensitive device arranged in direct correspondence with the light-transmitting display zone of the OLED display panel.

Since the display device includes the OLED display panel of the first aspect, it also has the same advantages as the OLED display panel. For details, reference may be made to the above description.

### BRIEF DESCRIPTION OF DRAWINGS

FIG. 1 is a cross-sectional view of a display device provided by an embodiment of the present application.

FIG. 2 is a front view of an OLED display panel provided by an embodiment of the present application.

FIG. 3 is a cross-sectional view of an OLED display panel provided by an embodiment of the present application.

FIG. 4 is a cross-sectional view of an OLED display panel provided by an embodiment of the present application.

FIG. 5 is a light path diagram of light-emitting sub-pixels of an OLED display panel provided by an embodiment of the present application.

FIG. 6 is a cross-sectional view of an OLED display panel provided by an embodiment of the present application.

FIG. 7 is a cross-sectional view of an OLED display panel provided by another embodiment of the present application.

FIG. 8 is a light path diagram of light-emitting sub-pixels of an OLED display panel provided by further embodiment of the present application.

FIG. 9 is a cross-sectional view of an OLED display panel provided by yet another embodiment of the present application.

FIG. 10 is a front view of an OLED display panel provided by an embodiment of the present application.

FIG. 11 is a front view of an OLED display panel provided by an embodiment of the present application.

FIG. 12 is a schematic diagram of the arrangement of first light-emitting sub-pixels and second light-emitting sub-pixels in a third display zone of an OLED display panel provided by an embodiment of the present application.

FIG. 13 is a cross-sectional view of an OLED display panel provided by an embodiment of the present application.

FIG. 14 is a schematic diagram of the structure of a third anode in the OLED display panel shown in FIG. 13.

### DETAILED DESCRIPTION OF EMBODIMENTS

As described in the background, in the related art, in order to improve the light transmittance of the light-transmitting display zone of the OLED display panel, the size of the light-emitting sub-pixels in the light-transmitting display zone is relatively small, and the spacing between the light-emitting sub-pixels is relatively large, thereby reducing the obstruction of the light-emitting sub-pixels to the external light entering the OLED display panel. However, due to the large spacing between the light-emitting sub-pixels, the display effect of the light-transmitting display zone is poor, for example, graininess or a screen-window effect would occur in the displayed image.

In view of the above technical problems, an embodiment of the present application provides an OLED display panel, which scatters or diffuses the colored light of the second light-emitting sub-pixels in the light-transmitting display zone through a light-transmitting film layer, thereby improving the light exit angle of the second light-emitting sub-pixels. Thereby, in the light-transmitting display zone, more of the light emitted by the second light-emitting sub-pixels is emitted from the region between the second light-emitting sub-pixels, improving the uniformity of emitted light in the light-transmitting display zone, and further improving the display effect of the OLED display panel in the light-transmitting display zone.

In order to make the above objectives, features and advantages of the embodiments of the present application more obvious and easy to understand, the technical solutions in the embodiments of the present application will be clearly and completely described below with reference to the drawings in the embodiments of the present application. Obviously, the described embodiments are only a part of the embodiments of the present application, not all of the embodiments. Based on the embodiments in the present application, all the other embodiments obtained by the person skilled in the art without creative work shall fall within the protection scope of the present application.

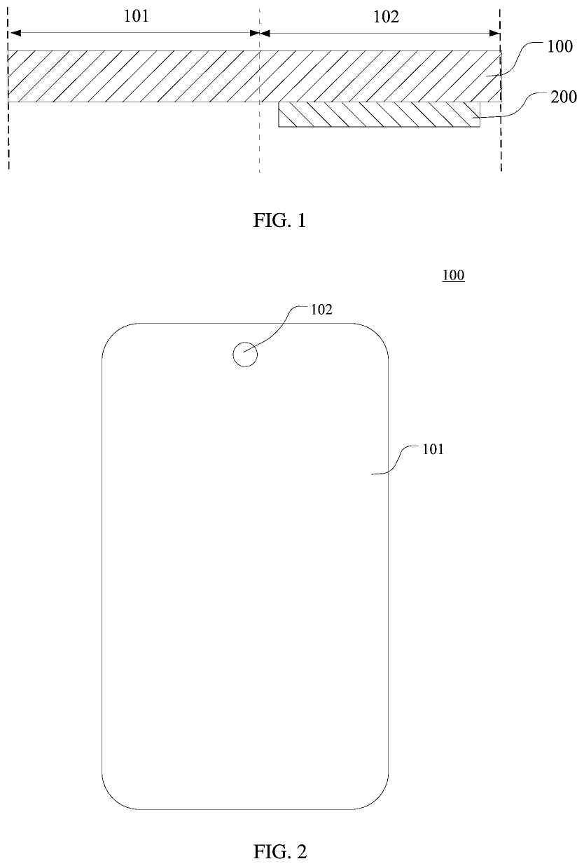

Referring to FIG. 1, a display device provided by an embodiment of the present application includes an OLED display panel 100, which is generally used for displaying information such as images, and realizing touch function. The display device may be any device with display function, for example, a mobile device such as a mobile phone, a tablet computer, a laptop, a palmtop computer, a vehicle-mounted electronic device, a wearable device, an ultra mobile personal computer (UMPC for short), a netbook or a personal digital assistant (PDA for short), and it may also be a non-mobile device such as a personal computer (PC for short), a television (TV for short), a teller machine or a self-service machine.

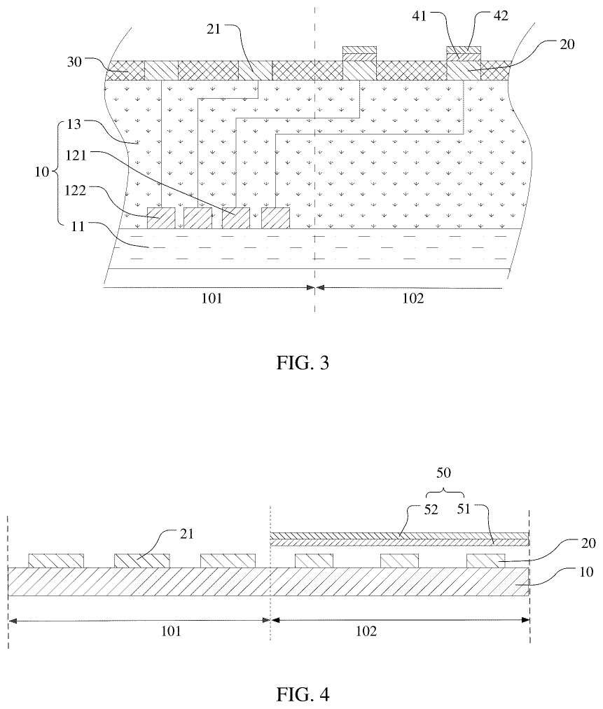

As shown in FIG. 2 and FIG. 3, the OLED display panel 100 has a light-transmitting display zone 102, and in the light-transmitting display zone 102, the external light can pass through the OLED display panel 100. In some embodiments, the entire surface of the OLED display panel 100 is the light-transmitting display zone 102, so as to realize the light-transmitting effect of the whole screen. In other embodiments, the OLED display panel 100 includes a main screen zone 101 and a light-transmitting display zone 102 adjacent to the main screen zone 101, and the main screen zone 101 at least partially surrounds the light-transmitting display zone 102. For example, in the embodiment shown in FIG. 2, the main screen zone 101 completely surrounds the light-transmitting display zone 102, and the main screen zone 101 may also partially surrounds the light-transmitting display zone 102, such as a notch screen of a mobile phone. As an example, the contour of the light-transmitting display zone may be in a shape of any one of a water droplet, a circle, a rectangle, an ellipse, a diamond, a semicircle, and a semi-ellipse.

As an example, as shown in FIG. 1, a photosensitive device is provided on the back of the OLED display panel 100, and is arranged in a direct correspondence to the light-transmitting display zone 102 of the OLED display panel 100. For example, the photosensitive device may be a camera 200, which corresponds to the position of the light-transmitting display zone 102, so that the external light signal passing through the light-transmitting display zone 102 is acquired for imaging. In other embodiments, the photosensitive device may also be a light sensor, a light transmitter, a distance sensor, and an ambient light sensor and the like. Referring to FIG. 3, the OLED display panel 100 includes an array substrate 10, a plurality of light-emitting sub-pixels arranged on the array substrate 10, and a pixel defining layer 30 for isolating respective light-emitting sub-pixels. The light-emitting sub-pixels include a plurality of second light-emitting sub-pixels 20 located in the light-transmitting display zone 102.

The array substrate 10 may be a thin film transistor (Thin Film Transistor, TFT for short) array substrate. As an example, the array substrate 10 may include a substrate 11, a driving circuit layer disposed on the substrate 11, and a planarization layer 13 (Planarization Layer, PLN for short) covering the driving circuit layer.

The substrate 11 may be a glass substrate, a flexible plastic substrate or a quartz substrate. The surface of the substrate 11 is provided with a plurality of gate lines arranged in a first direction and a plurality of data lines arranged in a second direction, and a zone defined by the gate lines and the data lines is configured to define light-emitting sub-pixels, with the first direction intersecting the second direction. A gate electrode of the thin film transistor is connected to the gate lines, a source electrode of the thin film transistor is connected to the data lines, and a drain electrode of each thin film transistor is electrically connected to its corresponding light-emitting sub-pixels. During display, under the control of the gate lines, the thin film transistor provides the data display signal input from the data lines to the light-emitting sub-pixels corresponding to the thin film transistor.

The driving circuit layer includes a plurality of second pixel circuits 121 for driving the second light-emitting sub-pixels 20 to emit light, and each second pixel circuit 121 may be connected with one second light-emitting sub-pixel 20 to drive the one second light-emitting sub-pixel 20. Or, each second pixel circuit 121 may be connected to a plurality of second light-emitting sub-pixels 20 to drive the plurality of second light-emitting sub-pixels 20, for example, two to four of second light-emitting sub-pixels 20 may be driven. As an example, the second pixel circuit 121 may be a 1T pixel circuit, a 2T1C pixel circuit, a 3T1C pixel circuit, a 3T2C pixel circuit, a 4T1C pixel circuit, a 5T1C pixel circuit, a 6T1C pixel circuit, a 7T1C pixel circuit, or a 7T2C pixel circuit.

In the embodiment in which the OLED display panel 100 includes the main screen zone 101 and the light-transmitting display zone 102, in order to improve the light transmittance of the light-transmitting display zone 102, as shown in FIG. 3, the second pixel circuits 121 connected with the light-emitting sub-pixels in the light-transmitting display zone 102 are located in the main screen zone 101 to avoid blocking the light passing through the light-transmitting display zone 102. In order to further improve the light transmittance of the light-transmitting display zone 102, the second pixel circuit 121 is connected to the light-emitting sub-pixel in the light-transmitting display zone 102 through a light-transmitting wire. The material of the light-transmitting wire may be at least one of indium tin oxide (ITO), indium zinc oxide (IZO), aluminum oxide zinc (AZO), gallium doped zinc oxide (GZO), zinc tin oxide (ZTO), gallium tin oxide (GTO), fluorine-doped tin oxide (FTO), zinc oxide (ZnOx), indium oxide (InOx), polyethylene dioxythiophene-polystyrene sulfonic acid (PEDOT:PSS), graphene, and carbon nanotubes.

The planarization layer 13 is generally located on the uppermost layer of the array substrate 10, and the upper surface of the planarization layer 13 is a flat surface, so as to form relatively flat film layers on the planarization layer 13. For example, the material of the planarization layer 13 may be an organic material, and the planarization layer 13 may be fabricated by coating or sputtering process.

The pixel defining layer 30 may be a silicon oxide layer, a silicon nitride layer or a transparent resin layer, and the pixel defining layer 30 may be formed by plasma chemical vapor deposition (PCVD) method, inkjet printing or spin coating, etc.

As shown in FIG. 3, the pixel defining layer 30 is used to isolate second light-emitting sub-pixels 20 from each other. Or, the pixel defining layer 30 is provided with a plurality of openings, and one second light-emitting sub-pixel 20, which is used to emit a specific color of light during display, is provided inside each opening. For example, the second light-emitting sub-pixel 20 includes a red light-emitting sub-pixel, a blue light-emitting sub-pixel and a green light-emitting sub-pixel.

As an example, the second light-emitting sub-pixel 20 includes a second anode, a second light-emitting layer on the second anode and a second cathode on the second light-emitting layer. By applying a positive voltage to the second anode and a negative voltage to the second cathode, the holes generated by the second anode are injected into the second light-emitting layer, and the electrons generated by the second cathode are injected into the second light-emitting layer. The electrons and holes, which are injected into the second light-emitting layer, recombine and excite light-emitting molecules in the second light-emitting layer, and the excited light-emitting molecules undergo radiation transition to make the corresponding second light-emitting sub-pixels 20 emit light. In some embodiments, the second anode is a reflective anode. The contour of the orthographic projection of the second anode on the substrate 11 has any one of the following shapes: water droplet shape, circle shape, rectangle shape, ellipse shape, diamond shape, semicircle shape or semi-ellipse shape. The material of the second anode is generally a material with a high work function in order to improve the hole injection efficiency, for example, it may be gold (Au), platinum (Pt), titanium (Ti), silver (Ag), indium tin oxide (ITO), indium zinc oxide (IZO) or transparent conductive polymer (such as polyaniline), etc.

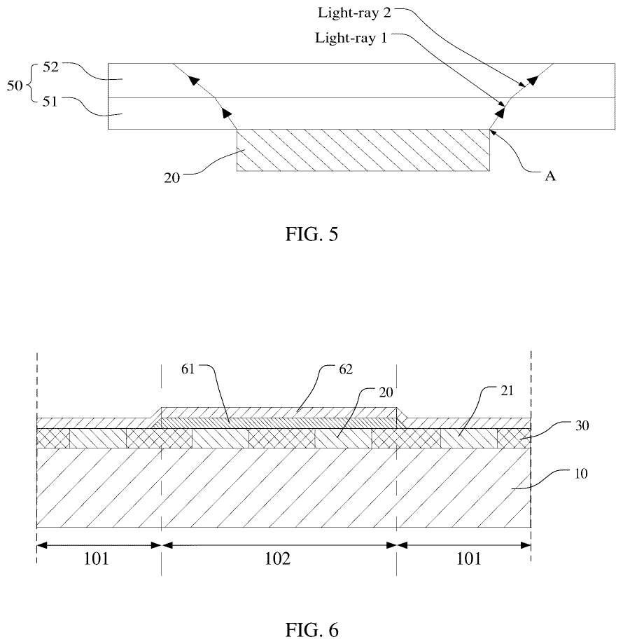

The material of the second cathode generally adopts a material with a lower work function, so as to facilitate electron injection, in addition to reducing the heat generated during operation and prolonging the service life of the OLED device. The material of the second cathode may be one of metal materials such as silver (Ag), aluminum (Al), lithium (Li), magnesium (Mg), ytterbium (Yb), calcium (Ca) or indium (In). It may also be an alloy of the aforementioned metal materials, such as magnesium-silver alloy (Mg/Ag) and lithium-aluminum alloy (Li/Al). Referring to FIG. 4, the light-transmitting display zone 102 may further include a light-transmitting film layer 50 arranged on the exit side of the second light-emitting sub-pixel 20, which is configured for scattering or diffusion of the colored light emitted from the second light-emitting sub-pixel 20. The light-transmitting film layer 50 at least includes a low-refractive-index film layer 52 and a high-refractive-index film layer 51 adjacent to the low-refractive-index film layer 52, where the refractive index of the low-refractive-index film layer 52 is lower than that of the high-refractive-index film layer 51. As shown in FIG. 5, the light emitted from a point A on the second light-emitting sub-pixel 20 that enters the high-refractive-index film layer 51 is marked as Light-ray 1, and the light entering the low-refractive-index film layer 52 is marked as Light-ray 2. When the light enters the low-refractive-index film layer 52 from the high-refractive-index film layer 51, the refraction angle will increase, causing the Light-ray 2 to be more divergent than the Light-ray 1, allowing more light to enter and be emitted from the region between second light-emitting sub-pixels 20, thereby improving the uniformity of light output in the light-transmitting display zone 102, so as to improve the display effect of the OLED display panel 100 in the light-transmitting display zone 102.

In the embodiment in which the camera 200 is arranged on the back of the OLED display panel 100, the high-refractive-index film layer 51 and the low-refractive-index film layer 52 are arranged so that more external light is received by the camera 200 through the OLED display panel 100, and the amount of light received by the camera 200 is increased, thereby improving the imaging effect of camera 200. As an example, a zone corresponding to the second light-emitting sub-pixel 20 is a light-emitting zone, and a region between adjacent second light-emitting sub-pixels 20 in the light-transmitting display zone 102 is a light-transmitting zone, where the light transmittance of the light-emitting zone is close to 0 and the light transmittance of the light-transmitting zone is greater than 40%.

Exemplarily, the high-refractive-index film layer 51 and the low-refractive-index film layer 52 may be fabricated using processes such as sputtering and coating, or they may be separately made into films and then attached to the second light-emitting sub-pixels 20 of the light-transmitting display zone 102. In an embodiment, as shown in FIG. 3, the high-refractive-index film layer 51 has a first light-transmitting structure 41 corresponding to the second light-emitting sub-pixel 20, and the orthographic projection of the first light-transmitting structure 41 on the substrate 11 covers the orthographic projection of the corresponding second light-emitting sub-pixel 20 on the substrate 11. The low-refractive-index film layer 52 has a second light-transmitting structure 42 corresponding to the first light-transmitting structure 41, and the orthographic projection of the second light-transmitting structure 42 on the substrate 11 covers the orthographic projection of corresponding first light-transmitting structure 41 on the substrate 11. For the same second light-emitting sub-pixel 20, the refractive index of the second light-transmitting structure 42 is lower than that of the first light-transmitting structure 41. Each of the second light-emitting sub-pixel 20 corresponds to a first light-transmitting structure 41 and a second light-transmitting structure 42.

Exemplarily, the OLED display panel 100 further includes an encapsulation structure covering a plurality of light-emitting sub-pixels 20. In order to simplify the manufacturing process of the OLED display panel 100, the high-refractive-index film layer 51 and the low-refractive-index film layer 52 may be formed by using the encapsulation structure. As shown in FIG. 6, the encapsulation structure includes a first encapsulation layer 61 covering each of the second light-emitting sub-pixels 20 of the light-transmitting display zone 102 and a second encapsulation layer 62 covering the first encapsulation layer 61. The first encapsulation layer 61 and the second encapsulation layer 62 may be fabricated using process such as sputtering and coating. The refractive index of the second encapsulation layer 62 is lower than that of the first encapsulation layer 61. The first encapsulation layer 61 forms the high-refractive-index film layer 51, and the second encapsulation layer 62 forms the low-refractive-index film layer 52. In the embodiment in which the OLED display panel 100 has a main screen zone 101, the light-emitting sub-pixels also include a plurality of first light-emitting sub-pixels 21 located in the main screen zone 101. The first encapsulation layer 61 may only be arranged in the light-transmitting display zone 102 as shown in FIG. 6, and the second encapsulation layer 62 covers each of the first light-emitting sub-pixels 21 in the main screen zone 101.

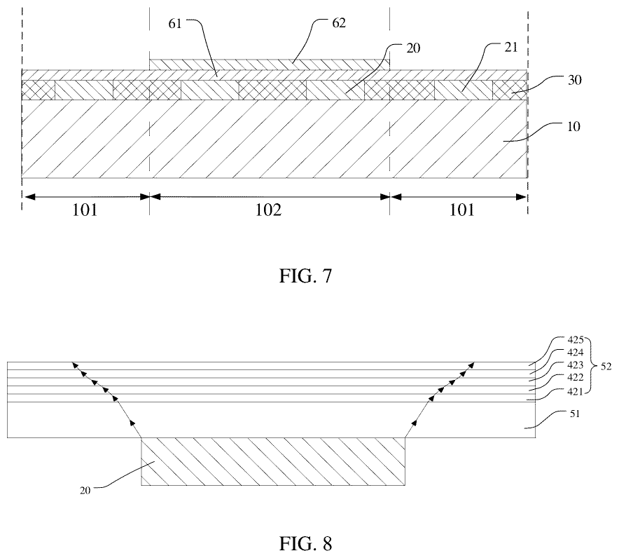

In another optional embodiment, as shown in FIG. 7, the first encapsulation layer 61 may cover each of the first light-emitting sub-pixels 21 of the main screen zone 101 as well as each of the second light-emitting sub-pixels 20 of the light-transmitting display zone 102. The second encapsulation layer 62 is located on the first encapsulation layer 61 and the orthographic projection of the second encapsulation layer 62 on the substrate 11 covers the orthographic projection of the second light-emitting sub-pixels 20 on the substrate 11.

Continuing with reference to FIG. 3, the driving circuit layer further includes a plurality of first pixel circuits 122 for driving the first light-emitting sub-pixels 21 to emit light, and each first pixel circuit 122 may be connected to one first light-emitting sub-pixel 21 so as to drive the one first light-emitting sub-pixel 21. Alternatively, each first pixel circuit 122 is connected to a plurality of first light-emitting sub-pixels 21 so as to drive the plurality of first light-emitting sub-pixels 21, for example, 2-4 first light-emitting sub-pixels 21 may be driven. As an example, the first pixel circuit 122 may be a 2T1C pixel circuit, a 3T1C pixel circuit, a 3T2C pixel circuit, a 4T1C pixel circuit, a 5T1C pixel circuit, a 6T1C pixel circuit, a 7T1C pixel circuit, or a 7T2C pixel circuit.

In order to improve the light transmittance of the light-transmitting display zone 102, compared to the size of the second light-emitting sub-pixel 20 located in the light-transmitting display zone 102, the size of the first light-emitting sub-pixel 21 in the main screen zone 101 is larger. In order to ensure the consistency of the luminance between the light-transmitting display zone 102 and the main screen zone 101, the range of data voltage of the second pixel circuit 121 is different from the range of data voltage of the first pixel circuit 122 in an embodiment. Exemplarily, the range of the data voltage of the second pixel circuit 121 is 3-6.5 volts, and the range of the data voltage of the first pixel circuit is 1-6.5 volts.

In some embodiments, the pixel density of a second light-emitting sub-pixel 20 is equal to the pixel density of a first light-emitting sub-pixel 21. In another embodiments, the pixel density of a second light-emitting sub-pixel 20 is smaller than the pixel density of a first light-emitting sub-pixel 21, so as to ensure the light transmittance of a light-transmitting display zone 102. As an example, the first light-emitting sub-pixel 21 includes a red light-emitting sub-pixel, a blue light-emitting sub-pixel, and a green light-emitting sub-pixel. The first light-emitting sub-pixel 21 includes a first anode, a first light-emitting layer located on the first anode, and a first cathode on the first light-emitting layer. By applying a positive voltage to the first anode and a negative voltage to the first cathode, the holes generated by the first anode are injected into the first light-emitting layer, and the electrons generated by the first cathode are injected into the first light-emitting layer. The electrons and holes, which are injected into the light-emitting layer, recombine and excite the light-emitting molecules in the first light-emitting layer, and the excited light-emitting molecules undergo radiation transition to make the corresponding first light-emitting sub-pixels 21 emit light. The material of the first anode is generally a material with a high work function in order to improve the hole injection efficiency, and may be gold (Au), platinum (Pt), titanium (Ti), silver (Ag), indium tin oxide (ITO), indium zinc oxide (IZO) or transparent conductive polymer (such as polyaniline), etc. The material of the first cathode generally adopts a material with a lower work function, so as to facilitate the injection of electrons, in addition to reducing the heat generated during operation and prolong the service life of the OLED device. The material of the first cathode may be one of metal materials such as silver (Ag), aluminum (Al), lithium (Li), magnesium (Mg), ytterbium (Yb), calcium (Ca) or indium (In). It may also be an alloy of the aforementioned metal materials, such as magnesium-silver alloy (Mg/Ag) and lithium-aluminum alloy (Li/Al).

The specific material of the first encapsulation layer 61 and the second encapsulation layer 62 is not limited, and any transparent material that meets the above-mentioned refractive index requirements may be used. For example, in an embodiment, the first encapsulation layer 61 is silicon oxynitride layer, and a second encapsulation layer 62 is a lithium fluoride layer or a magnesium fluoride layer, where the refractive indexes of lithium fluoride and magnesium fluoride are each 1.38, and the refractive index of silicon oxynitride is affected by the molar ratio of nitrogen to oxygen therein, which varies between 1.52-2.0.

Since silicon oxynitride itself has a relatively large adjustment gradient of refractive index, the greater the molar ratio of nitrogen to oxygen in silicon oxynitride, the greater the refractive index of the silicon oxynitride. Therefore, in another embodiment, the material of a first encapsulation layer 61 and a second encapsulation layer 62 are both silicon oxynitride, and the molar ratio of nitrogen to oxygen in the second encapsulation layer 62 is smaller than the molar ratio of nitrogen to oxygen in the first encapsulation layer 61, so that the refractive index of the second encapsulation layer 62 is lower than the refractive index of the first encapsulation layer 61.

The refractive indexes of respective positions of the low-refractive-index film layer 52 may be the same or different. In order to reduce the light loss when the light emitted by the second light-emitting sub-pixel 20 passes through the low-refractive-index film layer 52, in an embodiment, along the exiting direction of the OLED display panel 100, the refractive index of the low-refractive-index film layer 52 first decreases and then increases, so that the Light-ray 2 may gradually change the angle in the low-refractive-index film layer 52, thereby avoiding increase of the loss of light energy caused by the sudden change of the angle of the Light-ray 2. In order to realize the change of the refractive index of the low-refractive-index film layer 52, in an embodiment, the low-refractive-index film layer 52 includes at least three stacked light-transmitting layers, the refractive index of the light-transmitting layers in the same layer is the same, and the refractive index of the light-transmitting layers in the different layers first decreases and then increases along the exiting direction of the OLED display panel 100.

The layer number of the light-transmitting layer is not limited, as long as it meets the requirement of the above-mentioned refractive index change. For example, in an embodiment, the low-refractive-index film layer 52 includes three light-transmitting layers, and the refractive index of the light-transmitting layer in the middle is smaller than that of the light-transmitting layers on both sides. In another embodiment, as shown in FIG. 8, at least three light-transmitting layers sequentially include a first light-transmitting layer 421, a second light-transmitting layer 422, a third light-transmitting layer, a fourth light-transmitting layer 424 and a fifth light-transmitting layer 425 along the exiting direction of the OLED display panel 100, where the refractive index of the third light-transmitting layer 423 is the lowest, the refractive indexes of the second light-transmitting layer 422 and the fourth light-transmitting layer 424 are both greater than that of the third light-transmitting layer 423, the refractive index of the first light-transmitting layer 421 is greater than that of the second light-transmitting layer 422 and the refractive index of the fifth light-transmitting layer 425 is greater than that of the fourth light-transmitting layer 424. Referring to FIG. 8, when the light emitted by the second light-emitting sub-pixel 20 enters the low-refractive-index film layer 52, it sequentially passes through the first light-transmitting layer 421, the second light-transmitting layer 422, the third light-transmitting layer 423, the fourth light-transmitting layer 424 and the fifth light-transmitting layer 425, and the angle of the Light-ray 2 is gradually changed by gradual light refraction, so as to reduce the light energy loss of Light-ray 2.

The specific material of each light-transmitting layer is not limited, and any transparent material that meets the above-mentioned refractive index requirements may be adopted. In an embodiment in which the low-refractive-index film layer 52 includes three light-transmitting layers, the light-transmitting layer located in the middle is a lithium fluoride layer or a magnesium fluoride layer, and the light-transmitting layers located on both sides are silicon oxynitride layers. In another embodiments, each light-transmitting layer is a silicon oxynitride layer, and the molar ratio of nitrogen to oxygen in the light-transmitting layer of different layers first decreases and then increases along the exiting direction of the OLED display panel 100. For example, in the embodiment shown in FIG. 8, the first light-transmitting layer 421, the second light-transmitting layer 422, the third light-transmitting layer 423, the fourth light-transmitting layer 424 and the fifth light-transmitting layer 425 are all silicon oxynitride layers, and the molar ratio of nitrogen to oxygen in the second light-transmitting layer 422 and the fourth light-transmitting layer 424 is greater than the molar ratio of nitrogen to oxygen in the third light-transmitting layer 423, and the molar ratio of nitrogen to oxygen in the first light-transmitting layer 421 is greater than the molar ratio of nitrogen to oxygen in the second light-transmitting layer 422, and the molar ratio of nitrogen to oxygen in the fifth light-transmitting layer 425 is greater than the molar ratio of nitrogen to oxygen in the fourth light-transmitting layer 424.

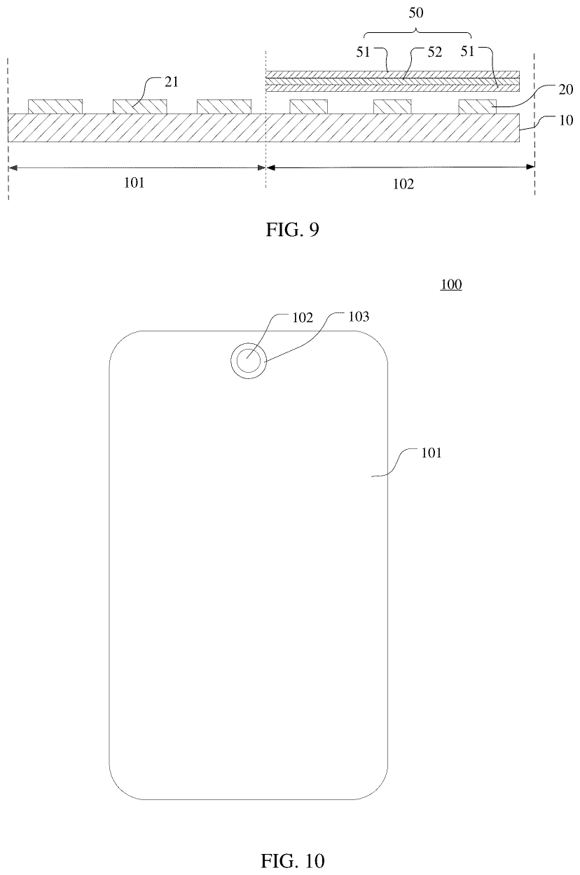

As shown in FIG. 9, the light-transmitting film layer 50 may further include a high-refractive-index film layer 51 located on the exiting side of the low-refractive-index film layer 52, that is, the light-transmitting film layer 50 is provided with two high-refractive-index film layers 51 and a low-refractive-index film layer 52 located between the two high-refractive-index film layers 51, allowing the light emitted from the second light-emitting sub-pixels 20 to diffuse without a large change in the light exit angle, thereby further improving the light exit uniformity of the OLED display panel 100.

Exemplarily, the refractive indexes of the two high-refractive-index film layers 51 are equal, thereby ensuring that the light exit angle of the light emitted from the second light-emitting sub-pixel 20 in the two high-refractive-index film layers 51 remains unchanged. Thereby, the light mixing effect between the second light-emitting sub-pixel 20 and the adjacent second light-emitting sub-pixel 20 is improved. In an embodiment in which the OLED display panel 100 has the main screen zone 101, setting the same refractive index for the two high-refractive-index film layers 51 may also ensure the consistency of the display results of the main screen zone 101 and the light-transmitting display zone 102.

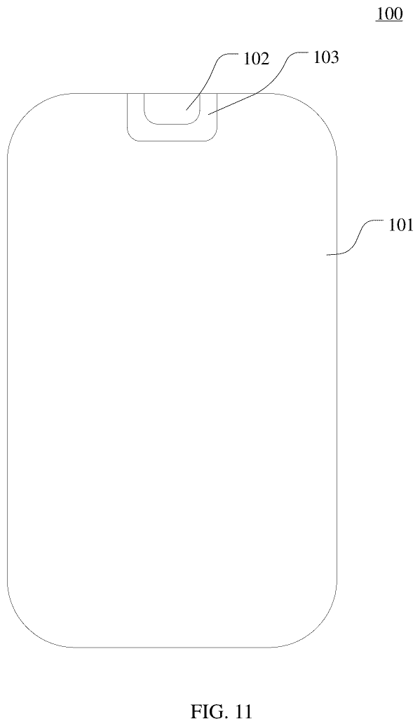

In an optional embodiment, as shown in FIG. 10, the OLED display panel 100 further includes a third display zone 103, which is located between the main screen zone 101 and the light-transmitting display zone 102. The third display zone 103 is a transition area between the main screen zone 101 and the light-transmitting display zone 102, which may be set as a ring or semi-ring structure adapted to the outer contour of the light-transmitting display zone 102. For example, in the embodiment shown in FIG. 10, the light-transmitting display zone 102 is circular, and the third display zone 103 is arranged as a circular ring around the light-transmitting display zone 102. For another example, in the embodiment shown in FIG. 11, the light-transmitting display zone 102 is located at the edge of the main screen zone 101 and is in a square shape, and the third display zone 103 is a semi-square ring arranged around the light-transmitting display zone 102.

In an embodiment, a third display zone 103 includes a first light-emitting sub-pixel 21 and a second light-emitting sub-pixel 22 arranged in an array, and the first light-emitting sub-pixel 21 is staggered with the second light-emitting sub-pixel 22. That is, in the third display zone 103, there are both the first light-emitting sub-pixel 21 with a larger size and the second light-emitting sub-pixel 20 with a smaller size, so that the transition between the main screen zone 101 and the light-transmitting display zone 102 is more natural, further improving the display uniformity of the OLED display panel 100.

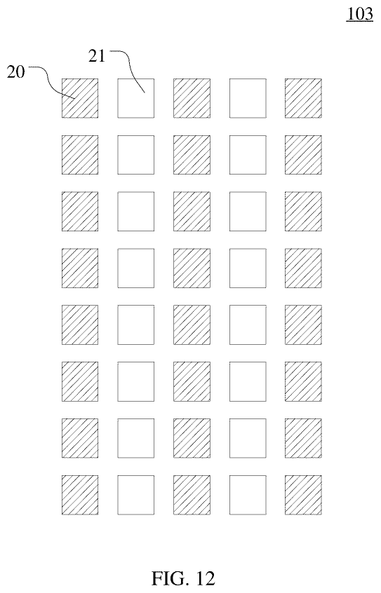

The first light-emitting sub-pixel 21 is staggered with a second light-emitting sub-pixel 22. For example, in some embodiments, as shown in FIG. 12, in a direction where the main screen zone 101 points towards the light-transmitting display zone 102, the first and second light-emitting sub-pixels are arranged in a manner of a first light-emitting sub-pixel column, a second light-emitting sub-pixel column, a first light-emitting sub-pixel column, a second light-emitting sub-pixel column . . . . In other embodiments, in each row and/or column of the light-emitting sub-pixels, they are arranged in a manner of a first light-emitting sub-pixel 21, a second light-emitting sub-pixel 20, a first light-emitting sub-pixel 21, a second light-emitting sub-pixel 20 . . . .

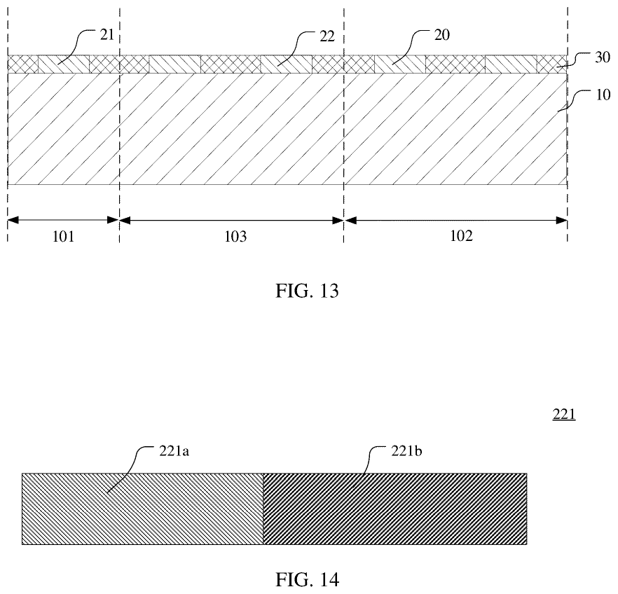

In an exemplary embodiment, in the direction where the main screen zone 101 points towards the light-transmitting display zone 102, the opening area of the first light-emitting sub-pixel 21 in the third display zone 103 gradually decreases, so that the actual light exit zone of the first light-emitting sub-pixel 21 gradually decreases in the direction where the main screen zone 101 points towards the light-transmitting display zone 102. In the display state, there is no obvious boundary between the main screen zone 101 and the light-transmitting display zone 102, which makes the transition area between the main screen zone 101 and the light-transmitting display zones 102 more natural, further optimizing the display effect of the OLED display panel 100. In another embodiment, as shown in FIG. 13 and FIG. 14, a third display zone 103 includes third light-emitting sub-pixels 22 arranged in an array, and the third light-emitting sub-pixel 22 include a third anode 221, a third light-emitting layer on the third anode 221 and a third cathode located on the third light-emitting layer. By applying a positive voltage to the third anode 221 and applying a negative voltage to the third cathode, holes generated by the third anode 221 are injected into the third light-emitting layer, and electrons generated by the third cathode are injected into the third light-emitting layer. The electrons and holes in the third light-emitting layer recombine and excite the light-emitting molecules in the third light-emitting layer, and the excited light-emitting molecules undergo radiation transition to make the corresponding the third light-emitting sub-pixels 22 emit light. The material of the third anode 221 is generally a material with a high work function in order to improve the hole injection efficiency, and may be gold (Au), platinum (Pt), titanium (Ti), silver (Ag), indium tin oxide (ITO), indium zinc oxide (IZO) or transparent conductive polymer (such as polyaniline), etc. The material of the third cathode generally adopts a material with a lower work function, so as to facilitate electron injection, in addition to reducing the heat generated during operation and prolonging the service life of the OLED device. The material of the third cathode may be one of metal materials such as silver (Ag), aluminum (Al), lithium (Li), magnesium (Mg), ytterbium (Yb), calcium (Ca) or indium (In), etc. It may also be an alloy of the aforementioned metal materials, such as magnesium-silver alloy (Mg/Ag) and lithium-aluminum alloy (Li/Al).

In an exemplary embodiment, as shown in FIG. 14, a third anode 221 includes a non-transparent anode zone 221a and a transparent anode zone 221b, where the non-transparent anode zone 221a is made of non-transparent anode material, and the transparent anode zone 221b is made of transparent anode material. Where, the specific shapes of the non-transparent anode zone 221a and the transparent anode zone 221b and relative positional relationship between them are not limited. For example, the non-transparent anode zone 221a and the transparent anode zone 221b may be arranged side by side. For another example, the non-transparent anode zone 221a is arranged around the transparent anode zone 221b, or the transparent anode zone 221b is arranged to surround the non-transparent anode zone 221a.

In the third light-emitting sub-pixels 22 in the direction where the main screen zone 101 points towards the light-transmitting display zone 102, the area proportion of the non-transparent anode zone 221a in the third anode 221 to the entire third anode 221 decreases sequentially, while the area proportion of the transparent anode zone 221b to the entire third anode 221 increases sequentially. In this way, in the direction where the main screen zone 101 points towards the light-transmitting display zone 102, the light transmittance of the third display zone 103 gradually increases, allowing the transition between the main screen zone 101 and the light-transmitting display zone 102 in the non-display state to be more natural, improving the integrity of the OLED display panel 100 in a non-display state.

In the OLED display panel 100 provided by the embodiments of the present application, the light-transmitting film layer 50 is stacked on each second light-emitting sub-pixel 20 in the light-transmitting display zone 102, and is configured for light scattering or diffusion of the colored light of the second light-emitting sub-pixel 20, thereby making more light enter a region between the second light-emitting sub-pixels 20 and exit from the region between the second light-emitting sub-pixels 20, further improving the light exit uniformity in the light-transmitting display zone 102 so as to enhance the display effect of the OLED display panel 100 in the light-transmitting display zone 102.

Finally, it should be noted that the above embodiments are only used to illustrate the technical solutions of the present application, but not to limit it; although the present application has been described in detail with reference to the foregoing embodiments, the persons skilled in the art should understand that: they may still modify the technical solutions recorded in the foregoing embodiments or equivalently replace parts or all of the technical features; while these modifications or replacements do not make the essence of the corresponding technical solutions deviate from the scope of the technical solutions of the embodiments in the present application.

What is claimed is:

1. An organic light emitting diode (OLED) display panel having a light-transmitting display zone, the light-transmitting display zone comprising:
a substrate;
a plurality of second light-emitting sub-pixels disposed on the substrate and configured to emit a specific color of light during display; and
a light-transmitting film layer disposed on an exit side of the second light-emitting sub-pixels and configured to scatter or diffuse colored light of the second light-emitting sub-pixels, the light-transmitting film layer at least comprising a low-refractive-index film layer and a high-refractive-index film layer adjacent to the low-refractive-index film layer; a refractive index of the low-refractive-index film layer being lower than that of the high-refractive-index film layer.

2. The organic light emitting diode display panel according to claim 1, wherein the high-refractive-index film layer has a first light-transmitting structure corresponding to the second light-emitting sub-pixel, and an orthographic projection of the first light-transmitting structure on the substrate covers an orthographic projection of corresponding second light-emitting sub-pixel on the substrate; and
the low-refractive-index film layer has a second light-transmitting structure corresponding to the first light-transmitting structure, and an orthographic projection of the second light-transmitting structure on the substrate covers an orthographic projection of corresponding first light-transmitting structure on the substrate.

3. The organic light emitting diode display panel according to claim 1, wherein the organic light emitting diode display panel comprises an first encapsulation layer covering each of the second light-emitting sub-pixels of the light-transmitting display zone and a second encapsulation layer covering the first encapsulation layer; the first encapsulation layer forms the high-refractive-index film layer; and the second encapsulation layer forms the low-refractive-index film layer.

4. The organic light emitting diode display panel according to claim 3, wherein the organic light emitting diode display panel is provided with a main screen zone, and the first encapsulation layer or the second encapsulation layer covers each of the first light-emitting sub-pixels of the main screen zone.

5. The organic light emitting diode display panel according to claim 3, wherein the first encapsulation layer is silicon oxynitride layer, and the second encapsulation layer is a lithium fluoride layer or a magnesium fluoride layer; or
the first encapsulation layer and the second encapsulation layer are both made of silicon oxynitride, and the molar ratio of nitrogen to oxygen in the second encapsulation layer is smaller than that in the first encapsulation layer.

6. The organic light emitting diode display panel according to claim 1, wherein along an exiting direction of the OLED display panel, the refractive index of the low-refractive-index film layer first decreases and then increases.

7. The organic light emitting diode display panel according to claim 6, wherein the low-refractive-index film layer comprises at least three stacked light-transmitting layers;
the light-transmitting layers in the same layer have the same refractive index; and
refractive indexes of the light-transmitting layers in different layers first decrease and then increase along the exiting direction of the OLED display panel.

8. The organic light emitting diode display panel according to claim 7, wherein the low-refractive-index film layer comprises three light-transmitting layers, the light-transmitting layer located in the middle is a lithium fluoride layer or a magnesium fluoride layer, and the light-transmitting layers located on both sides are silicon oxynitride layers; or,
the light-transmitting layers are each silicon oxynitride layers, and the molar ratio of nitrogen to oxygen in the light-transmitting layer of different layers first decreases and then increases along the exiting direction of the OLED display panel.

9. The organic light emitting diode display panel according to claim 1, wherein a zone corresponding to the second light-emitting sub-pixel is a light-emitting zone, and a zone between adjacent second light-emitting sub-pixels in the light-transmitting display zone is a light-transmitting zone; a light transmittance of the light-transmitting zone is greater than 40%.

10. The organic light emitting diode display panel according to claim 1, wherein the second light-emitting sub-pixel comprises a second anode, a second light-emitting layer on the second anode and a second cathode on the second light-emitting layer, the second anode is a reflective anode, a contour of an orthographic projection of the second anode on the substrate has any one of the following shapes: water droplet shape, circle shape, rectangle shape, ellipse shape, diamond shape, semicircle shape or semi-ellipse shape.

11. The organic light emitting diode display panel according to claim 1, further comprising a main screen zone comprising a plurality of first light-emitting sub-pixels, the first light-emitting sub-pixel comprises a first anode, a first light-emitting layer located on the first anode, and a first cathode on the first light-emitting layer.

12. The organic light emitting diode display panel according to claim 1, further comprising a driving circuit layer comprising a plurality of second pixel circuits and a plurality of first pixel circuits, wherein a range of data voltage of a second pixel circuit is different from that of data voltage of a first pixel circuit.

13. The organic light emitting diode display panel according to claim 12, wherein the range of data voltage of the second pixel circuit is 3-6.5 volts, and the range of data voltage of the first pixel circuit is 1-6.5 volts.

14. The organic light emitting diode display panel according to claim 1, wherein the organic light emitting diode display panel also comprises a main screen zone, the main screen zone comprises a plurality of first light-emitting sub-pixels; a pixel density of the second light-emitting sub-pixel is smaller than that of the first light-emitting sub-pixel.

15. The organic light emitting diode display panel according to claim 1, further comprising:
a main screen zone comprising a plurality of first light-emitting sub-pixels; and
a third display zone located between the main screen zone and the light-transmitting display zone.

16. The organic light emitting diode display panel according to claim 15, wherein the third display zone comprises first light-emitting sub-pixels and second light-emitting sub-pixels arranged in an array, and the first light-emitting sub-pixels are staggered with the second light-emitting sub-pixels.

17. The organic light emitting diode display panel according to claim 16, wherein in a direction where the main screen zone points towards the light-transmitting display zone, opening areas of the first light-emitting sub-pixels in the third display zone gradually decrease.

18. The organic light emitting diode display panel according to claim 15, wherein the third display zone comprises third light-emitting sub-pixels arranged in an array, and the third light-emitting sub-pixel comprises a third anode, a third light-emitting layer on the third anode and a third cathode located on the third light-emitting layer; the third anode comprises a non-transparent anode zone and a transparent anode zone; in the third light-emitting sub-pixel in a direction where the main screen zone points towards the light-transmitting display zone, an area proportion of the non-transparent anode zone in the third anode to the entire third anode decreases sequentially, while an area proportion of the transparent anode zone to the entire third anode increases sequentially.

19. The organic light emitting diode display panel according to claim 1, wherein a contour of the light-transmitting display zone has a shape of one of a: water droplet shape, circle shape, rectangle shape, ellipse shape, diamond shape, semicircle shape or semi-ellipse shape.

20. A display device, comprising the organic light emitting diode display panel according to claim 1; and
a photosensitive device disposed in direct correspondence with the light-transmitting display zone of the OLED display panel and comprising at least one of a light sensor, a light transmitter, a distance sensor, and an ambient light sensor.
